(19) United States
(12) Patent Application Publication
(10) Pub. No.: US 2021/0381098 A1
(43) Pub. Date: Dec. 9, 2021

(54) SPUTTERING TARGET

(71) Applicant: MITSUBISHI MATERIALS CORPORATION, Tokyo (JP)

(72) Inventors: Yujiro Hayashi, Sanda-shi (JP); Yuichi Kondo, Sanda-shi (JP); Masahiro Shoji, Sanda-shi (JP)

(73) Assignee: MITSUBISHI MATERIALS CORPORATION, Tokyo (JP)

(21) Appl. No.: 17/288,138

(22) PCT Filed: Nov. 20, 2019
(86) PCT No.: PCT/JP2019/045407

§ 371 Date: Apr. 23, 2021

(30) Foreign Application Priority Data
Nov. 20, 2018 (JP) 2018-217177
Nov. 18, 2019 (JP) 2019-207865

(51) Int. Cl. C23C 14/34

(52) U.S. Cl. CPC C23C 14/3414

(57) ABSTRACT

A sputtering target contains Ge, Sb, and Te and has a high-oxygen region with a high oxygen concentration and a low-oxygen region having a lower oxygen concentration than the high-oxygen region, and has a structure in which the low-oxygen regions are dispersed in island form in a matrix of the high-oxygen region. In the sputtering target, voids with a diameter of 0.5 μm or more and 5.0 μm or less may be present in a range of 2 or more and 10 or less in a range of 0.12 mm² for the average density.

### TECHNICAL FIELD

The present invention relates to a sputtering target used when forming a Ge—Sb—Te alloy film able to be used as a recording film for a phase change recording medium or a semiconductor non-volatile memory, for example.

Priority is claimed on Japanese Patent Application No. 2018-217177, filed Nov. 20, 2018, and Japanese Patent Application No. 2019-207865, filed Nov. 18, 2019, the contents of which are incorporated herein by reference.

### BACKGROUND ART

Generally, in phase change recording medium such as DVD-RAM, semiconductor non-volatile memory (Phase Change RAM (PCRAM)), and the like, a recording film formed of a phase change material is used. In a recording film formed of such a phase change material, reversible phase change between crystal and amorphous is caused by heating by laser light irradiation or Joule heat and the difference of reflectivity or electrical resistance between crystal and amorphous is made to correspond to 1 and 0, thereby realizing non-volatile storage. As a recording film formed of a phase change material, a Ge—Sb—Te alloy film is widely used.

The Ge—Sb—Te alloy film described above is formed using a sputtering target, for example, as shown in Patent Documents 1 to 5.

In the sputtering targets described in Patent Documents 1 to 5, an ingot of a Ge—Sb—Te alloy having a desired composition is prepared, the ingot is pulverized to obtain a Ge—Sb—Te alloy powder, and the obtained Ge—Sb—Te alloy powder is pressed and sintered, that is, by a powder sintering method, to carry out the manufacturing.

Patent Document 1 proposes a technique for suppressing the generation of abnormal discharge by having no pores having an average diameter of 1 μm or more present in the sputtering target and limiting the number of pores present in a sintered body such that the number of pores having an average diameter of 0.1 to 1 μm is 100 or less per 4000 μm².

Patent Document 2 discloses that the total amount of carbon, nitrogen, oxygen, and sulfur, which are gas components, in the sputtering target is limited to 700 ppm or less.

Patent Documents 3 and 4 propose a technique for suppressing the generation of cracks in a sputtering target when sputtering is performed at a high output by setting the oxygen concentration in the sputtering target to 5000 wtppm or more.

Patent Document 5 proposes a technique for suppressing the generation of abnormal discharge and suppressing cracks in a sputtering target by specifying the oxygen content in the sputtering target as 1500 to 2500 wtppm and specifying the average particle size of the oxide.

### CITATION LIST

### Patent Document

[Patent Document 1]
Japanese Patent No. 4885305

[Patent Document 2]
Japanese Patent No. 5420594

[Patent Document 3]
Japanese Patent No. 5394481

[Patent Document 4]
Japanese Patent No. 5634575

[Patent Document 5]
Japanese Patent No. 6037421

### SUMMARY OF INVENTION

### Technical Problem

As described in Patent Document 1, in a case where the number of pores is limited, it is not possible to alleviate stress generated during machining or thermal stress generated during bonding to the backing material and there was a concern that cracks may be generated during machining or during bonding.

As described in Patent Document 2, even in a case where the oxygen content is limited to a low amount and the number of pores is reduced as a result, there was a concern that cracks may be generated during machining or during bonding to a backing material.

In a case where the oxygen concentration is set as high as 5000 wtppm or more as in Patent Documents 3 and 4, there was a concern that abnormal discharge may be easily generated during sputtering and stable sputtering film formation may not be possible. In addition, at the time of bonding, there was a concern that it may not be possible to suppress the generation of cracks due to thermal expansion.

Although Patent Document 5 specifies the oxygen content and specifies the particle size of the oxide, there was a concern that it may not be possible to sufficiently suppress the generation of abnormal discharge and it may not be possible to sufficiently suppress the generation of cracks during machining or bonding to the backing material.

The invention is created in consideration of the circumstances described above and has an object of providing a sputtering target which is able to suppress the generation of abnormal discharge, which is able to suppress the generation of cracks during machining and bonding to a backing material, and which is capable of stably forming a Ge—Sb—Te alloy film.

### Solution to Problem

As a result of intensive studies by the present inventors in order to solve the problems described above, it was found that, due to the presence, in a high-oxygen region having a high oxygen concentration, of island-like low-oxygen regions having a lower oxygen concentration than the high-oxygen region, stress during machining and thermal stress during bonding are alleviated by the high-oxygen region and it is possible to suppress the generation of cracks during machining and during bonding, and that, due to the presence of the island form low-oxygen regions, it is possible to sufficiently suppress the generation of abnormal discharge. In the sputtering targets of Patent Documents 1 to 5, a structure in which island form low-oxygen regions are present in such a high-oxygen region is not known.

The present invention is created based on the above findings and a sputtering target of one aspect of the present invention is a sputtering target containing Ge, Sb, and Te, having a high-oxygen region with a high oxygen concentration and a low-oxygen region having a lower oxygen concentration than the high-oxygen region, and having a structure in which the low-oxygen regions are dispersed in island form in the matrix of the high-oxygen region.

Since the sputtering target of the aspect has a high-oxygen region with a high oxygen concentration and low-oxygen regions having a lower oxygen concentration than the high-oxygen region and has a structure in which the low-oxygen regions are dispersed in island form in the matrix of the high-oxygen region, stress during machining and thermal stress during bonding are alleviated by the high-oxygen region and it is possible to suppress the generation of cracks during machining and during bonding. On the other hand, the island form low-oxygen regions having a low oxygen concentration being present makes it possible to sufficiently suppress the generation of abnormal discharge during sputtering.

In the sputtering target of the aspect, preferably, voids with a diameter of 0.5 μm or more and 5.0 μm or less are present in a range of 2 or more and 10 or less in a range of 0.12 mm² as an average density.

In this case, since 2 or more voids with a diameter of 0.5 μm or more and 5.0 μm or less are present in a range of 0.12 mm² for the average density, the voids alleviate stress during machining and thermal stress during bonding and it is possible to further suppress the generation of cracks during machining and during bonding. On the other hand, since voids with a diameter of 0.5 μm or more and 5.0 μm or less are limited to 10 or less in a range of 0.12 mm² for the average density, it is possible to further suppress the generation of abnormal discharge during sputtering.

Preferably, the sputtering target of the aspect further contains one type or two or more types additive elements selected from C, In, Si, Ag, and Sn, and the total content of the additive elements is 25 atom % or less. The total content of the additive elements may be 3 atom % or more.

In this case, since it is possible to improve various characteristics of the sputtering target and the formed Ge—Sb—Te alloy film by appropriately adding the additive elements described above, such addition may be carried out as appropriate according to the required characteristics. In a case where the additive elements described above are added, it is possible to sufficiently ensure the basic characteristics of the sputtering target and the formed Ge—Sb—Te alloy film by limiting the total content of the additive elements to 25 atom % or less.

### Advantageous Effects of Invention

According to the above aspect of the present invention, it is possible to provide a sputtering target which is able to suppress the generation of abnormal discharge, which is able to suppress the generation of cracks during machining or during bonding to a backing material, and which is capable of stably forming a Ge—Sb—Te alloy film.

### BRIEF DESCRIPTION OF DRAWINGS

FIG. 1 is a schematic diagram showing a structure of a sputtering target which is an embodiment of the present invention.

FIG. 2 is a flow chart showing a method for manufacturing a sputtering target which is an embodiment of the present invention.

### DESCRIPTION OF EMBODIMENTS

A description will be given of the sputtering target which is an embodiment of the present invention with reference to the drawings.

The sputtering target of the present embodiment is used, for example, when forming a Ge—Sb—Te alloy film used as a phase change recording medium or a phase change recording film of a semiconductor non-volatile memory. However, the Ge—Sb—Te alloy film obtained by the present invention is not limited to being used as a phase change recording medium or a phase change recording film of a semiconductor non-volatile memory and the use thereof for other purposes as necessary is also possible.

The sputtering target of the present embodiment contains Ge, Sb, and Te as main components and specifically has a composition in which Ge is 10 atom % or more and 30 atom % or less, Sb is 15 atom % or more and 35 atom % or less, and the remainder is Te and unavoidable impurities. The Ge content is more preferably 15 atom % or more and 25 atom % or less, and even more preferably 20 atom % or more and 23 atom % or less. The Sb content is more preferably 15 atom % or more and 25 atom % or less, and even more preferably 20 atom % or more and 23 atom % or less. The Te content is more preferably 40 atom % or more and 65 atom % or less, and even more preferably 53 atom % or more and 57 atom % or less.

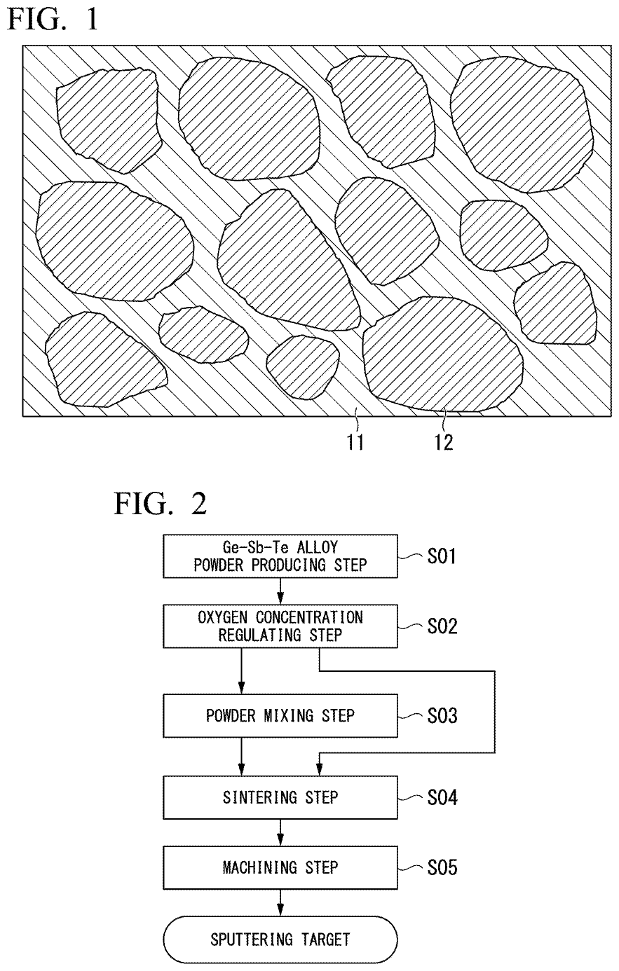

As shown in FIG. 1, the sputtering target of the present embodiment has a high-oxygen region 11 having a high oxygen concentration and low-oxygen regions 12 having a lower oxygen concentration than the high-oxygen region 11, and a structure in which the low-oxygen regions 12 are dispersed in island form in the matrix of the high-oxygen region 11. It is preferable that the low-oxygen regions 12 are divided by the high-oxygen region 11 to be independent of each other.

The high-oxygen region 11 is, for example, set to a range where the oxygen concentration is 10000 mass ppm or more and 15000 mass ppm or less. The low-oxygen regions 12 are set to a range where the oxygen concentration is 2000 mass ppm or more and 5000 mass ppm or less. It is preferable that there are almost no regions having an oxygen concentration in the range of 5000 mass ppm to 10000 mass ppm.

In the high-oxygen region 11, the oxygen concentration is more preferably 11000 mass ppm or more and 14000 mass ppm or less, and the oxygen concentration is even more preferably 12000 mass ppm or more and 13000 mass ppm or less. In the low-oxygen regions 12, the oxygen concentration is more preferably 2500 mass ppm or more and 4000 mass ppm or less, and the oxygen concentration is even more preferably 3000 mass ppm or more and 3500 mass ppm or less.

In the sputtering target of the present embodiment, the total oxygen concentration is in a range of 2000 mass ppm or more and 5000 mass ppm or less. The lower limit of the oxygen concentration in the entire sputtering target is more preferably 2500 mass ppm or more, and even more preferably 3000 mass ppm or more. On the other hand, the upper limit of the oxygen concentration in the entire sputtering target is more preferably 4500 mass ppm or less, and even more preferably 4000 mass ppm or less.

In the present embodiment, the area ratio of the low-oxygen regions 12 is larger than the area ratio of the high-oxygen region 11. Specifically, the area ratio of the low-oxygen regions 12 is in a range of 60% or more and 80% or less, and the remainder is the high-oxygen region 11. The lower limit of the area ratio of the low-oxygen regions 12 is more preferably 63% or more, and even more preferably 65% or more. On the other hand, the upper limit of the area ratio of the low-oxygen regions 12 is more preferably 75% or less, and even more preferably 70% or less. It is possible to calculate the area ratio of the low-oxygen regions 12 by performing an image analysis of the observation image by EPMA using analysis software.

Although not limited thereto, it is preferable that the average size of the low-oxygen region 12 in the observation image by EPMA corresponds to a diameter of 1 to 20 μm in a case of being converted into a circle having the same area. The diameter is more preferably 3 to 15 μm, and even more preferably 5 to 10 μm.

Furthermore, in the sputtering target of the present embodiment, for the average density, voids with a diameter of 0.5 μm or more and 5.0 μm or less are preferably present in a range of 2 or more and 10 or less in a range of 0.12 mm². It is possible to determine the average density, for example, by the method below. The observation sample is observed by EPMA, any three points in the central section of the observation material are observed at a magnification of 300 times, and the average value of the number of voids per 0.12 mm² is measured. In this case, an image of the observed secondary electron image is prepared, void portions are extracted by binarization processing with image processing software, a diameter d of a circle having the same area is calculated as the equivalent circle diameter from the area S of each void (calculated from S=πd²), and the number of voids with a diameter of 0.5 μm or more and 5.0 μm or less in the calculated equivalent circle diameter may be examined.

The lower limit of the number of voids with a diameter of 0.5 μm or more and 5.0 μm or less observed in a range of 0.12 mm² is more preferably 3 or more as the average density, and even more preferably 4 or more.

On the other hand, the upper limit of the number of voids with a diameter of 0.5 μm or more and 5.0 μm or less observed in the range of 0.12 mm² is more preferably 9 or less as the average density, and even more preferably 8 or less.

For the diameter of the voids described above, the cross-sectional area of the observed voids is measured and the equivalent circle diameter calculated from this cross-sectional area is used.

More preferably, voids with a diameter of 1.0 μm or more and 5.0 μm or less are present in a range of 1 or more and 9 or less in a range of 0.12 mm² for the average density. The lower limit of the number of voids is more preferably 2 or more, and even more preferably 3 or more. On the other hand, the upper limit of the number of voids is more preferably 8 or less, and even more preferably 7 or less.

In addition to Ge, Sb, and Te, the sputtering target of the present embodiment may contain one type or two or more types of additive elements selected from C, In, Si, Ag, and Sn, as necessary. In a case where the additive elements described above are added, the total content of these additive elements is set to 25 atom % or less.

In a case where the additive elements are added in the sputtering target of the present embodiment, the total content thereof is more preferably 20 atom % or less, and even more preferably 15 atom % or less. The lower limit value of the additive element is not particularly limited, but in order to reliably improve various characteristics, 3 atom % or more is more preferable, and 5 atom % or more is even more preferable.

Next, a description will be given of a method for manufacturing a sputtering target of the present embodiment with reference to the flow chart of FIG. 2.

(Ge—Sb—Te Alloy Powder Producing Step S01)

First, the Ge raw material, the Sb raw material, and the Te raw material are weighed so as to have a predetermined blending ratio. It is preferable to use Ge raw materials, Sb raw materials, and Te raw materials having a purity of 99.9 mass % or more, respectively.

The blending ratio of the Ge raw material, the Sb raw material, and the Te raw material is appropriately set according to the final target composition of the Ge—Sb—Te alloy film to be formed.

The Ge raw material, the Sb raw material, and the Te raw material weighed as described above are charged into a melting furnace and melted. The Ge raw material, the Sb raw material, and the Te raw material are melted in a vacuum or in an inert gas atmosphere (for example, Ar gas). In the case of melting in a vacuum, the degree of vacuum is preferably 10 Pa or less. In the case of melting in an inert gas atmosphere, it is preferable to perform vacuum replacement up to 10 Pa or less, and then introduce an inert gas (for example, Ar gas) to a pressure of atmospheric pressure or less.

The obtained molten metal is poured into a casting mold to obtain a Ge—Sb—Te alloy ingot. The casting method is not particularly limited.

This Ge—Sb—Te alloy ingot is pulverized in an atmosphere of an inert gas (for example, Ar gas) to obtain a Ge—Sb—Te alloy powder (raw material powder) having an average particle size of 0.1 μm or more and 120 μm or less. The method for pulverizing the Ge—Sb—Te alloy ingot is not particularly limited, but, in the present embodiment, it is possible to use a vibration mill.

(Oxygen Concentration Regulating Step S02)

Next, the obtained Ge—Sb—Te alloy powder is held in an air atmosphere at room temperature in a range of 20 hours or more and 30 hours or less. Due to this, the surface layer of the Ge—Sb—Te alloy powder is oxidized to form an oxide layer, and the oxygen concentration in the Ge—Sb—Te alloy powder is adjusted. The oxidation temperature is more preferably 15° C. or higher and 30° C. or lower, and even more preferably 20° C. or higher and 25° C. or lower.

The oxygen concentration in the Ge—Sb—Te alloy powder after being held in the air atmosphere is preferably in a range of 2800 mass ppm or more and 4500 mass ppm or less with respect to the total mass of the alloy powder. The lower limit of the oxygen concentration in the Ge—Sb—Te alloy powder after being held in the air atmosphere is more preferably 2900 mass ppm or more, and even more preferably 3000 mass ppm or more. On the other hand, the upper limit of the oxygen concentration in the Ge—Sb—Te alloy powder after being held in the air atmosphere is more preferably 4200 mass ppm or less, and even more preferably 4000 mass ppm or less.

(Powder Mixing Step S03)

Next, in a case where the additive elements described above are added, the powder having the additive element (alloy powder of a part or all of the additive elements and/or powder of each additive element) is mixed with the Ge—Sb—Te alloy powder in which the oxygen concentration is adjusted. The mixing method is not particularly limited, but, in the present embodiment, it is possible to use a ball mill.

(Sintering Step S04)

Next, the raw material powder obtained as described above is filled in a molding die, heated while being pressed, and sintered to obtain a sintered body. As the sintering method, it is possible to apply hot pressing, HIP, or the like.

In the sintering step S04, by holding for 1 hour or more and 6 hours or less in a low temperature region of 280° C. or higher and 350° C. or lower, water on the surface of the raw material powder is removed, then the temperature is raised to a sintering temperature of 560° C. or higher and 590° C. or lower and held for 6 hours or more and 15 hours or less to proceed with the sintering.

When the holding time in the low temperature region in the sintering step S04 is less than 1 hour, there is a concern that the removal of water may be insufficient such that the oxygen concentration in the obtained sintered body may increase. On the other hand, when the holding time in the low temperature region exceeds 6 hours, there is a concern that the oxide layer formed on the surface layer of the Ge—Sb—Te alloy powder may change form and that it may not be possible to form the high-oxygen region. Therefore, in the present embodiment, the holding time in the low temperature region is set in a range of 1 hour or more and 6 hours or less.

The lower limit of the holding time in the low temperature region in the sintering step S04 is more preferably 1.5 hours or more, and even more preferably 2 hours or more. On the other hand, the upper limit of the holding time in the low temperature region in the sintering step S04 is more preferably 5.5 hours or less, and even more preferably 5 hours or less.

When the holding time at the sintering temperature in the sintering step S04 is less than 6 hours, there are concerns that the sintering may be insufficient, that the mechanical strength may be lacking, and that cracks may occur during handling or during sputtering. On the other hand, when the holding time at the sintering temperature in the sintering step S04 exceeds 15 hours, there was a concern that the sintering may proceed more than necessary. Therefore, in the present embodiment, the holding time at the sintering temperature in the sintering step S04 is set in a range of 6 hours or more and 15 hours or less.

The lower limit of the holding time at the sintering temperature in the sintering step S04 is more preferably 7 hours or more, and even more preferably 8 hours or more. On the other hand, the upper limit of the holding time at the sintering temperature in the sintering step S04 is more preferably less than 14 hours, and even more preferably less than 12 hours.

(Machining Step S05)

Next, the obtained sintered body is subjected to machining so as to have a predetermined size.

The sputtering target of the present embodiment is manufactured by the above steps.

As shown in FIG. 1, since the sputtering target of the present embodiment having the above configuration has the high-oxygen region 11 having a high oxygen concentration and the low-oxygen regions 12 having a lower oxygen concentration than the high-oxygen region 11 and has a structure in which the low-oxygen regions 12 are dispersed in island form in the matrix of the high-oxygen region 11, the stress during machining and the thermal stress during bonding are alleviated by the high-oxygen region 11 and it is possible to suppress the generation of cracks during machining and during bonding. On the other hand, due to the presence of the low-oxygen regions 12 having a low oxygen concentration, it is possible to sufficiently suppress the generation of abnormal discharge during sputtering.

Furthermore, in the present embodiment, in a case where voids with a diameter of 0.5 μm or more and 5.0 μm or less are present in a range of 2 or more and 10 or less in a range of 0.12 mm² for the average density, the stress during machining and the thermal stress during bonding are further alleviated by the voids, it is possible to further suppress the generation of cracks during machining and during bonding, and it is possible to suppress the generation of abnormal discharge during sputtering due to the voids.

In a case where the sputtering target of the present embodiment further contains one type or two or more types of additive elements selected from C, In, Si, Ag, and Sn, and the total content of the additive elements is 25 atom % or less, it is possible to improve various characteristics of the sputtering target and the formed Ge—Sb—Te alloy film and it is possible to sufficiently ensure the basic characteristics of the sputtering target and the formed Ge—Sb—Te alloy film.

For example, since the Ge—Sb—Te alloy film of the present embodiment is used as a recording film, the additive elements described above may be appropriately added so as to obtain an appropriate chemical, optical, and electrical response as the recording film.

Furthermore, in the present embodiment, the area ratio of the low-oxygen regions 12 is larger than the area ratio of the high-oxygen region 11, thus, it is possible to further suppress the generation of abnormal discharge during sputtering.

In addition, by setting the area ratio of the low-oxygen regions 12 to 60% or more, it is possible to further suppress the generation of abnormal discharge during sputtering. On the other hand, by setting the area ratio of the low-oxygen regions 12 to 80% or less, the area ratio of the high-oxygen region 11 is secured, it is possible to reliably alleviate the stress during machining and the thermal stress during bonding by the high-oxygen region 11, and it is possible to more reliably suppress the generation of cracks during machining and during bonding.

In addition, in the present embodiment, in the oxygen concentration regulating step S02, the obtained Ge—Sb—Te alloy powder is held in an air atmosphere at room temperature in a range of 20 hours or more and 30 hours or less, the surface layer of the Ge—Sb—Te alloy powder is oxidized to form an oxide layer and the oxygen concentration in the Ge—Sb—Te alloy powder is adjusted, thus, it is possible to stably manufacture a sintered body with a structure in which the low-oxygen regions 12 are dispersed in island form in the matrix of the high-oxygen region 11.

Although the embodiments of the present invention are described above, the present invention is not limited thereto, and it is possible to make appropriate changes within a range not departing from the technical idea of the invention.

### EXAMPLES

A description will be given below of the results of confirmation experiments performed to confirm the effectiveness of the present invention.

(Sputtering Target)

As raw materials to be melted, Ge raw materials, Sb raw materials, and Te raw materials each having a purity of 99.9 mass % or more were prepared. These Ge raw materials, Sb raw materials, and Te raw materials were weighed at the blending ratios shown in Table 1. The weighed Ge raw material, Sb raw material, and Te raw material were charged into a melting furnace, melted in an Ar gas atmosphere at normal pressure, and the obtained molten metal was poured into a casting mold and naturally cooled to room temperature to obtain a Ge—Sb—Te alloy ingot. The size of the ingot was 90 mm×50 mm×40 mm.

The obtained Ge—Sb—Te alloy ingot was pulverized using a vibration mill in an Ar gas atmosphere at normal pressure, and a Ge—Sb—Te alloy powder (raw material powder) passed through a 90 μm sieve was obtained. The amount of oxygen was adjusted with respect to the obtained Ge—Sb—Te alloy powder under the conditions shown in Table 2. In a case where the additive elements shown in Table 1 were added, a predetermined amount of the additive element powder was mixed with the Ge—Sb—Te alloy powder after being held in the air atmosphere.

The obtained raw material powder was filled in a carbon hot press molding die and held in a vacuum atmosphere of 5 Pa at the temperature, holding time, and pressurizing pressure shown in Table 2, and then pressing and sintering (hot pressing) were carried out at the sintering temperature, the holding time at the sintering temperature, and the pressurizing pressure shown in Table 2 to obtain a sintered body. The obtained sintered body was subjected to machining to manufacture a sputtering target (126 mm×178 mm×6 mm) for evaluation. Then, the items below were evaluated.

(Structure)

An observation sample was taken from the obtained sputtering target, the cross section was observed by EPMA (electron probe microanalyzer), and it was confirmed whether or not low-oxygen regions were dispersed in island form in the matrix of the high-oxygen region as shown in FIG. 1. As the observation samples, four 10 mm×10 mm×6 mm sample pieces were each cut out for use from specific positions of the sputtering target for evaluation: 10 mm from the outer peripheral portion at the central section of each side. The model name of the EPMA used is JXF-8500F and the analytical capability of the semi-quantitative analysis is 3 nm square.

The observation was made at a magnification of 1000 times and scanning was carried out with a spectroscope to collect the X-ray spectrum. By semi-quantitative analysis of EPMA, regions having an oxygen concentration in the range of 2000 mass ppm or more and 5000 mass ppm or less were identified as “low-oxygen regions”, and regions having an oxygen concentration in the range of 10000 mass ppm or more and 15000 mass ppm or less were identified as “high-oxygen regions”. The analysis method is surface analysis in a range of 280 μm×380 μm.

In Table 3, cases of a structure in which the low-oxygen regions were distributed in island form in the matrix of the high-oxygen region are denoted as “0” and cases of not having the structure described above (for example, a case where only the low-oxygen region or high-oxygen region is present, a case where the low-oxygen region and the high-oxygen region are each present in local areas, and a case where the high-oxygen regions are dispersed in island form in the matrix of the low-oxygen region) are denoted as “X”.

(Voids)

The observation sample was observed by EPMA, any three points in the central section of the observation material were observed at a magnification of 300 times, and the average value of the number of voids per 0.12 mm² was measured. First, an image of the observed secondary electron image was prepared, void portions were extracted by binarization processing with image processing software, and the diameter d of a circle having the same area was calculated as the equivalent circle diameter from the area S of each void (calculated from S=πd²). Then, the number of voids with a diameter of 0.5 μm or more and 5.0 μm or less in the calculated equivalent circle diameter was examined. The evaluation results are shown in Table 3.

(Density of Sputtering Target)

The dimensions of a test piece taken from the prepared sputtering target were measured using calipers and the weight was measured with an electronic balance to calculate the measured density. The theoretical density of the sputtering target was calculated as follows from the composition of the blending ratio of the sputtering target. In a case where the molar ratio of Ge:Sb:Te:(additive element) is a:b:c:d, weight Wa when Ge is the a mol is calculated, and volume Va when Ge is the a mol is calculated from the weight Wa and the density of the metal Ge. Similarly, calculation is carried out for weight Wb and volume Vb when Sb is the b mol, weight Wc and volume Vc when Te is the c mol, and weight Wd and volume Vd when (additive elements) are the d mol. Then, the theoretical density was calculated by dividing (total weight of each element=Wa+Wb+Wc+Wd) by (total volume of each element=Va+Vb+Vc+Vd). From the obtained theoretical density and measured density, the relative density was calculated by the formula below. The evaluation results are shown in Table 3.

(Relative density)=(Measured density)/(Theoretical density)×100 (%)

(Oxygen Concentration)

Material broken during processing of the sputtering target was crushed into powder, a measurement sample was taken from this powder, and gas analysis was performed. The measurement results are shown in Table 3. In the gas analysis, the graphite crucible in which the sample was placed was heated at a high frequency, melted in an inert gas, and detected by an infrared absorption method to perform the analysis.

(Cracks During Machining)

The sintered body described above was processed using a lathe under the conditions of a rotation speed of 250 rpm and a feed of 0.1 mm and the state of generation of chipping and cracks during processing was confirmed.

A case where no chipping or cracks were confirmed was evaluated as “0”, a case where chipping or cracks were confirmed but sputtering was possible was evaluated as “A”, and a case where sputtering was not possible due to chipping or cracks was evaluated as “X”.

(Cracks During Bonding)

The sputtering target described above was bonded to a backing plate made of Cu using In solder. The bonding was performed under conditions in which the heating temperature was 200° C., the applied pressure was 3 kg, and the cooling was natural cooling. A case in which no cracks were confirmed in the bonding was evaluated as “0” and a case in which cracks were confirmed in the bonding was evaluated as “X”.

(Abnormal Discharge)

The sputtering target described above was bonded to a backing plate made of Cu using In solder. This was attached to a magnetron sputtering apparatus and, after carrying out exhaust to 1×10⁻⁴ Pa, sputtering was carried out under conditions of an Ar gas pressure of 0.3 Pa, an input power of DC 500 W, and a target-board distance of 70 mm.

The number of abnormal discharges during sputtering was measured as the number of abnormal discharges in one hour from the start of discharge, by the arc count function of a DC power supply (model number: RPDG-50A) manufactured by MKS Instruments. The evaluation results are shown in Table 3.

(Anti-Folding Strength)

A measurement sample was taken from the sputtering target and the three-point bending strength was measured based on the JIS R 1601 standard. The evaluation results are shown in Table 3.

TABLE 1

| | | Mixing Ratio (atom %) | | | | | | | |
|---|---|---|---|---|---|---|---|---|---|
| | | | | Additive elements | | | | | |
| | | Ge | Sb | C | In | Si | Ag | Sn | Te |
| Examples | 1 | 22.2 | 22.2 | — | — | — | — | — | Remainder |
| | 2 | 22.2 | 22.2 | — | — | — | — | — | Remainder |
| | 3 | 22.2 | 22.2 | — | — | — | — | — | Remainder |
| | 4 | 20.0 | 40.0 | — | — | — | — | — | Remainder |
| | 5 | 20.0 | 20.0 | — | — | — | 20.0 | — | Remainder |
| | 6 | 20.0 | 20.0 | 20.0 | — | — | — | — | Remainder |
| | 7 | 17.0 | 17.0 | — | 25.0 | — | — | — | Remainder |
| | 8 | 20.0 | 20.0 | — | — | 20.0 | — | — | Remainder |
| | 9 | 20.0 | 20.0 | — | — | — | — | 20.0 | Remainder |
| Comparative | 1 | 22.2 | 22.2 | — | — | — | — | — | Remainder |
| Examples | 2 | 22.2 | 22.2 | — | — | — | — | — | Remainder |
| | 3 | 22.2 | 22.2 | — | — | — | — | — | Remainder |

TABLE 2

| | | Powder oxygen amount adjustment | | | | | | | | | |
|---|---|---|---|---|---|---|---|---|---|---|---|
| | | | | | Oxygen | Low temperature holding conditions | | | Sintering Conditions | | |
| | | | | Holding | amount | | Holding | Pressing | | Holding | Pressing |
| | | | | Time | (mass | Temperature | Time | pressure | Temperature | Time | pressure |
| | | Atmosphere | Temperature | (hours) | ppm) | (° C.) | (hours) | (MPa) | (° C.) | (hours) | (MPa) |
| Examples | 1 | Air | Room | 24 | 3500 | 350 | 1 | 15 | 580 | 7 | 15 |
| | | | temperature | | | | | | | | |
| | 2 | Air | Room | 24 | 3400 | 350 | 1 | 5 | 580 | 7 | 5 |
| | | | temperature | | | | | | | | |
| | 3 | Air | Room | 24 | 3600 | 350 | 1 | 30 | 580 | 7 | 30 |
| | | | temperature | | | | | | | | |
| | 4 | Air | Room | 24 | 3300 | 350 | 1 | 5 | 580 | 7 | 5 |
| | | | temperature | | | | | | | | |
| | 5 | Air | Room | 24 | 3100 | 350 | 1 | 5 | 580 | 7 | 5 |
| | | | temperature | | | | | | | | |
| | 6 | Air | Room | 24 | 3300 | 350 | 1 | 5 | 580 | 7 | 5 |
| | | | temperature | | | | | | | | |
| | 7 | Air | Room | 24 | 3400 | 350 | 1 | 5 | 580 | 7 | 5 |
| | | | temperature | | | | | | | | |
| | 8 | Air | Room | 24 | 3200 | 350 | 1 | 5 | 580 | 7 | 5 |
| | | | temperature | | | | | | | | |
| | 9 | Air | Room | 24 | 3200 | 350 | 1 | 5 | 580 | 7 | 5 |
| | | | temperature | | | | | | | | |
| Comparative | 1 | Air | 350° C. | 6 | 6100 | 350 | 1 | 5 | 580 | 7 | 5 |
| Examples | 2 | — | — | — | 1000 | 350 | 1 | 15 | 580 | 7 | 15 |
| | 3 | Air | 350° C. | 1 | 2900 | 350 | 1 | 5 | 580 | 7 | 5 |

TABLE 3

| | | | | | | | | | | Abnormal | |
|---|---|---|---|---|---|---|---|---|---|---|---|
| | | | Oxygen Amount (mass ppm) | | | | | | | discharge | Anti- |
| | | | Low- | High- | | Number | Relative | Cracks | | generation | folding |
| | | | oxygen | oxygen | | of pores | density | During | During | number | strength |
| | | Structure | region | region | Whole | (pores) | (%) | machining | bonding | (times/hour) | (MPa) |
| Examples | 1 | ◯ | 2800 | 12500 | 3100 | 2 | 98.6 | ◯ | ◯ | 2 | 83 |
| | 2 | ◯ | 2600 | 12200 | 3000 | 7 | 94.7 | ◯ | ◯ | 5 | 76 |
| | 3 | ◯ | 3000 | 13100 | 3300 | 0 | 99.0 | Δ | ◯ | 28 | 82 |
| | 4 | ◯ | 2700 | 12900 | 3000 | 8 | 93.8 | ◯ | ◯ | 5 | 75 |
| | 5 | ◯ | 2500 | 12400 | 2800 | 6 | 94.5 | ◯ | ◯ | 3 | 74 |
| | 6 | ◯ | 2800 | 12800 | 3000 | 12 | 94.0 | ◯ | ◯ | 12 | 70 |
| | 7 | ◯ | 2800 | 12700 | 3000 | 9 | 94.6 | ◯ | ◯ | 7 | 74 |
| | 8 | ◯ | 2600 | 13000 | 2900 | 9 | 93.8 | ◯ | ◯ | 6 | 75 |
| | 9 | ◯ | 2500 | 12100 | 2800 | 6 | 94.1 | ◯ | ◯ | 4 | 76 |
| Comparative | 1 | X | 3200 | 58000 | 5800 | 18 | 96.3 | ◯ | X | — | 68 |
| Examples | 2 | X | — | — | 900 | 0 | 99.7 | X | X | — | 84 |
| | 3 | X | 2200 | 45000 | 2600 | 3 | 94.9 | ◯ | X | — | 77 |

In Comparative Example 1 in which the Ge—Sb—Te alloy powder was held at 350° C. for 6 hours in an air atmosphere, the oxygen concentration in the Ge—Sb—Te alloy powder was 6100 mass ppm. The structure after sintering was a structure in which high-oxygen regions were dispersed in the matrix of the low-oxygen region. The amount of oxygen in the high-oxygen region was extremely high at 58000 mass ppm and GeO₂ was confirmed in a part of the low-oxygen region.

In this Comparative Example 1, cracks were confirmed during bonding. Therefore, the number of generated abnormal discharges was not evaluated.

In Comparative Example 2 in which an oxygen concentration adjusting process was not performed with respect to the Ge—Sb—Te alloy powder, the oxygen concentration in the Ge—Sb—Te alloy powder was 1000 mass ppm. The structure after sintering was a structure in which only the low-oxygen region was present. By setting the pressurizing pressure at the time of sintering to be high, the number of voids with a diameter of 0.5 μm or more and 5.0 μm or less was 0.

In this Comparative Example 2, cracks were confirmed during machining and during bonding. Therefore, the number of generated abnormal discharges was not evaluated.

In Comparative Example 3 in which the Ge—Sb—Te alloy powder was held at 350° C. for 1 hour in an air atmosphere, the oxygen concentration in the Ge—Sb—Te alloy powder was 2900 mass ppm. The structure after sintering was a structure in which high-oxygen regions were dispersed in the matrix of the low-oxygen region. The amount of oxygen in the high-oxygen region was extremely high at 45000 mass ppm and GeO₂ was confirmed in a part of the low-oxygen region.

In this Comparative Example 3, cracks were confirmed during bonding. Therefore, the number of generated abnormal discharges was not evaluated.

In contrast to the above, in Examples 1 to 9 of the present invention in which the Ge—Sb—Te alloy powder was held at room temperature for 24 hours in the air atmosphere, the oxygen concentration in the Ge—Sb—Te alloy powder was 3100 to 3500 mass ppm. The structure after sintering was a structure in which low-oxygen regions were dispersed in the matrix of the high-oxygen region.

In these Examples 1 to 9 of the present invention, no cracks were confirmed during bonding. The number of generated abnormal discharges was also kept low.

In Example 3 of the present invention in which the pressurizing pressure during sintering was 30 MPa, the number of voids with a diameter of 0.5 μm or more and 5.0 μm or less was 0 and minute cracks were confirmed during machining. For this reason, during sputtering, the number of generated abnormal discharges was relatively large due to the minute cracks.

Accordingly, in order to sufficiently suppress the generation of cracks during machining, the pressurizing pressure during sintering is preferably set such that the number of voids with a diameter of 0.5 μm or more and 5.0 μm or less is 2 or more. In Example 6 of the present invention, the number of voids (pores) was 12, but the number of abnormal discharges was 12, which was larger than that of other Examples of the present invention, but within an acceptable range.

As described above, according to the Examples of the present invention, it is confirmed that it is possible to sufficiently suppress the generation of abnormal discharges, to sufficiently suppress the generation of cracks during machining or during bonding to a backing material, and to provide a sputtering target capable of stably forming a Ge—Sb—Te alloy film.

### REFERENCE SIGNS LIST

11: High-oxygen region
12: Low-oxygen region

1. A sputtering target comprising Ge, Sb, and Te,
wherein the sputtering target has a high-oxygen region and low-oxygen regions having a lower oxygen concentration than the high-oxygen region, and has a structure in which the low-oxygen regions are dispersed in island form in a matrix of the high-oxygen region.

2. The sputtering target according to claim 1,
wherein voids with a diameter of 0.5 μm or more and 5.0 μm or less are present in a range of 2 or more and 10 or less in a range of 0.12 mm2 as an average density.

3. The sputtering target according to claim 1, further comprising one or two or more of additive elements selected from C, In, Si, Ag, and Sn,
wherein a total content of the additive elements is 25 atom % or less.

4. The sputtering target according to claim 1,
wherein a content of Ge is 10 atom % or more and 30 atom % or less,
a content of Sb is 15 atom % or more and 35 atom % or less, and
a remainder is Te and unavoidable impurities.

5. The sputtering target according to claim 3,
wherein a content of Ge is 10 atom % or more and 30 atom % or less,
a content of Sb content is 15 atom % or more and 35 atom % or less,
a total content of the additive elements is 3 atom % or more and 25 atom % or less, and
a remainder is Te and unavoidable impurities.

6. The sputtering target according to claim 1,
wherein an oxygen concentration in the high-oxygen region is 10000 mass ppm or more and 15000 mass ppm or less, and an oxygen concentration in the low-oxygen region is 2000 mass ppm or more and 5000 mass ppm or less.

7. The sputtering target according to claim 1,
wherein, when a cross section of the sputtering target is observed with an electron probe microanalyzer, an area ratio of the low-oxygen regions in the cross section is 60% or more and 80% or less and a remainder is the high-oxygen region.
